(19) United States
(12) Patent Application Publication
(10) Pub. No.: US 2026/0020478 A1
(43) Pub. Date: Jan. 15, 2026

(54) DISPLAY DEVICE AND ELECTRONIC DEVICE INCLUDING THE SAME

(71) Applicant: SAMSUNG DISPLAY CO., LTD., YONGIN-SI (KR)

(72) Inventors: Byung Hoon KANG, Yongin-si (KR); Tae Hyeog JUNG, Yongin-si (KR); Seong Jin HWANG, Yongin-si (KR)

(21) Appl. No.: 19/199,543

(22) Filed: May 6, 2025

(30) Foreign Application Priority Data
Jul. 11, 2024 (KR) 10-2024-0091676

(51) Int. Cl. H10K 59/80; H10K 102/00

(52) U.S. Cl. CPC H10K 59/873; H10K 2102/311

(57) ABSTRACT

A display device is provided. The display device comprises a display panel comprising a folding area and a non-folding area, and a cover window disposed on the display panel and comprising a groove overlapping the folding area, wherein the cover window comprises a resin layer disposed in the groove, and wherein the resin layer has a Young's modulus of 30 MPa to 1 GPa at −20° C.

This application claims priority from Korean Patent Application No. 10-2024-0091676 filed on Jul. 11, 2024 in the Korean Intellectual Property Office, the disclosure of which is herein incorporated by reference in its entirety.

### BACKGROUND

### 1. Field of the Disclosure

The present disclosure relates to a display device.

### 2. Description of the Related Art

As the information-oriented society evolves, various demands for display devices are ever increasing. For example, display devices are being employed by various electronic devices such as smart phones, digital cameras, laptop computers, navigation devices, and smart televisions.

Display devices may be flat panel display devices such as a liquid-crystal display device, a field emission display device, and a light-emitting display device. Light-emitting display devices include an organic light-emitting display device including organic light-emitting elements, an inorganic light-emitting display device including inorganic light-emitting elements such as inorganic semiconductor, and a micro light-emitting display device including micro light-emitting elements.

Recently, foldable display devices are getting a lot of attention. A foldable display device has the advantages of both a smart phone and a tablet PC because it is easy to carry and can have a wide screen. Whenever a foldable display device is folded, stress may be applied to different layers of the display device. As some of the layers are exposed to such stress as folding and unfolding are repeated, defects such as cracks may occur.

### SUMMARY

Aspects of the present disclosure provide a display device with improved folding reliability.

It should be noted that objects of the present disclosure are not limited to the above-mentioned object; and other objects of the present disclosure will be apparent to those skilled in the art from the following descriptions.

According to an aspect of the present disclosure, a display device comprises a display panel comprising a folding area and a non-folding area, and a cover window disposed on an upper surface of the display panel and comprising a groove overlapping the folding area, wherein the cover window further comprises a resin layer disposed in the groove, and wherein the resin layer has a Young's modulus of 30 MPa to 1 GPa at −20° C.

In an embodiment, the cover window includes a first surface adjacent to the upper surface of the display panel and a second surface opposite to the first surface of the cover window, and the groove is formed at the first surface of the cover window.

In an embodiment, the resin layer has a Young's modulus of 20 MPa to 2 GPa at 25° C.

In an embodiment, the cover window includes a first surface adjacent to the upper surface of the display panel and a second surface opposite to the first surface of the cover window, and the groove is formed at the second surface of the cover window.

In an embodiment, the resin layer has a Young's modulus of 10 MPa to 2 GPa at 25° C.

In an embodiment, a difference between a refractive index of the resin layer and a refractive index of the cover window is equal to or less than 0.0009.

In an embodiment, the display device further comprises a polarizing member disposed between the display panel and the cover window, a cover window protection layer disposed on the cover window, a window coupling member disposed between the polarizing member and the cover window, and a protection layer coupling member disposed between the cover window and the cover window protection layer.

In an embodiment, the resin layer is in contact with one of the window coupling member and the protection layer coupling member.

In an embodiment, the display device further comprises a polymer film layer disposed under a lower surface, opposite to the upper surface, of the display panel, a barrier member disposed under the polymer film layer, and a metal plate disposed under the barrier member.

According to an aspect of the present disclosure, a display device comprises a display panel comprising a folding area and a non-folding area, and a cover window disposed on the display panel, wherein the cover window comprises a flat portion overlapping the non-folding area, a slim portion provided with a groove and overlapping the folding area and having a thickness smaller than the flat portion and located on an upper surface of the cover window, and a resin layer disposed in the groove of the slim portion and having a Young's modulus of 10 MPa to 2 GPa at 25° C.

In an embodiment, the resin layer has a Young's modulus of 30 MPa to 1 GPa at −20° C.

In an embodiment, a difference between a refractive index of the resin layer and a refractive index of the cover window is equal to or less than 0.0009.

In an embodiment, the display device further comprises a cover window protection layer disposed on the cover window, and a protection layer coupling member disposed between the cover window and the cover window protection layer, wherein the resin layer is in contact with the protection layer coupling member.

In an embodiment, the display device further comprises a polarizing member disposed between the display panel and the cover window, a polarizing member coupling member disposed between the display panel and the polarizing member, and a window coupling member disposed between the polarizing member and the cover window.

In an embodiment, the display device further comprises a polymer film layer disposed under the display panel, a barrier member disposed under the polymer film layer, and a metal plate disposed under the barrier member.

According to an aspect of the present disclosure, a display device comprises a display panel comprising a folding area and a non-folding area, and a cover window disposed on the display panel, wherein the cover window comprises a flat portion overlapping the non-folding area, a slim portion provided with a groove and overlapping the folding area and having a thickness smaller than the flat portion and located on a lower surface of the cover window, and a resin layer disposed in the groove of the slim portion and having a Young's modulus of 20 MPa to 2 GPa at 25° C.

In an embodiment, the resin layer has a Young's modulus of 30 MPa to 1 GPa at −20° C.

In an embodiment, a difference between a refractive index of the resin layer and a refractive index of the cover window is equal to or less than 0.0009.

In an embodiment, the display device further comprises a polarizing member disposed between the display panel and the cover window, and a window coupling member disposed between the polarizing member and the cover window. The resin layer is in contact with the window coupling member.

In an embodiment, the display device further comprises a cover window protection layer disposed on the cover window, a protection layer coupling member disposed between the cover window and the cover window protection layer, a polymer film layer disposed under the display panel, a barrier member under the polymer film layer and a metal plate disposed under the barrier member.

Aspects of the present disclosure provide a display device in which the modulus of a resin layer of a cover window is different between at room temperature and at a low temperature depending on the location the resin layer, so that the strain applied to the cover window during folding can be reduced and cracks can be prevented in the resin layer, thereby preventing a cover window protection layer from being delaminated.

According to an aspect of the present disclosure, an electronic device includes a processor, a memory having stored application programs for execution by the processor, a display panel comprising a display panel comprising a folding area and a non-folding area, and a cover window disposed on an upper surface of the display panel and including a groove overlapping the folding area, wherein the cover window further comprises a resin layer disposed in the groove, and wherein the resin layer has a Young's modulus of 30 MPa to 1 GPa at −20° C., and a user interface configured to sense user input via touch or cursor select of an icon presented on the display panel, wherein the processor is caused to execute one or more of the stored application programs upon receipt of the user input.

It should be noted that effects of the present disclosure are not limited to those described above and other effects of the present disclosure will be apparent to those skilled in the art from the following descriptions.

### BRIEF DESCRIPTION OF THE DRAWINGS

The above and other aspects and features of the present disclosure will become more apparent by describing in detail embodiments thereof with reference to the attached drawings, in which:

FIG. 1 is a perspective view of a display device according to an embodiment of the present disclosure.

FIG. 2 is a perspective view showing the display device when it is folded according to an embodiment of the present disclosure.

FIG. 3 is an exploded perspective view of the display device shown in FIG. 1 according to an embodiment of the present disclosure.

FIG. 4 is a cross-sectional view of the display device, taken along line A-A′ of FIG. 1, according to an embodiment of the present disclosure.

FIG. 5 is a cross-sectional view of a display panel according to an embodiment of the present disclosure.

FIG. 6 is an enlarged view of area AA of FIG. 4 according to an embodiment of the present disclosure.

FIG. 7 is a cross-sectional view schematically showing the display device when it is folded according to an embodiment of the present disclosure.

FIG. 8 is a cross-sectional view schematically showing a display device according to an embodiment of the present disclosure.

FIG. 9 is an enlarged view of area BB of FIG. 8 according to an embodiment of the present disclosure.

FIG. 10 is a cross-sectional view schematically showing the display device when it is folded according to an embodiment of the present disclosure.

FIG. 11 is a graph showing results of a pen drop test of cover windows according to an embodiment of the present disclosure.

FIG. 12 is a graph showing results of a pen pressure test of cover windows according to an embodiment of the present disclosure.

FIG. 13 is a diagram illustrating an electronic device according to an embodiment of the present invention.

### DETAILED DESCRIPTION OF THE EMBODIMENTS

The present invention will now be described more fully hereinafter with reference to the accompanying drawings, in which preferred embodiments of the invention are shown. This invention may, however, be embodied in different forms and should not be construed as limited to the embodiments set forth herein. Rather, these embodiments are provided so that this disclosure will be thorough and complete, and will filly convey the scope of the invention to those skilled in the art.

It will also be understood that when a layer is referred to as being “on” another layer or substrate, it can be directly on the other layer or substrate, or intervening layers may also be present. The same reference numbers indicate the same components throughout the specification.

It will be understood that, although the terms “first,” “second,” etc. may be used herein to describe various elements, these elements should not be limited by these terms. These terms are only used to distinguish one element from another element. For instance, a first element discussed below could be termed a second element without departing from the teachings of the present invention. Similarly, the second element could also be termed the first element.

Each of the features of the various embodiments of the present disclosure may be combined or combined with each other, in part or in whole, and technically various interlocking and driving are possible. Each embodiment may be implemented independently of each other or may be implemented together in an association. Hereinafter, embodiments of the present disclosure will be described with reference to the accompanying drawings.

The present inventive concept relates to a display device that includes a cover window provided with a resin layer to secure repeated folding and unfolding operations without delamination of a cover window protection layer on the cover window or crack in the cover window. The cover window may have a groove at its upper surface or lower surface to accommodate the resin layer. The resin layer may have a Young's modulus of 30 MPa to 1 GPa at −20° C. The Young's modulus of the resin layer is different at different temperatures (e.g., at the room temperature and at a lower temperature) depending on the location the resin layer, so that the strain applied to the cover window during folding can be reduced and cracks in the resin layer can be prevented, thereby preventing a cover window protection layer from being delaminated. Hereinafter, a Young's modulus of a layer or a constituent element of a display device may be referred to as a modulus.

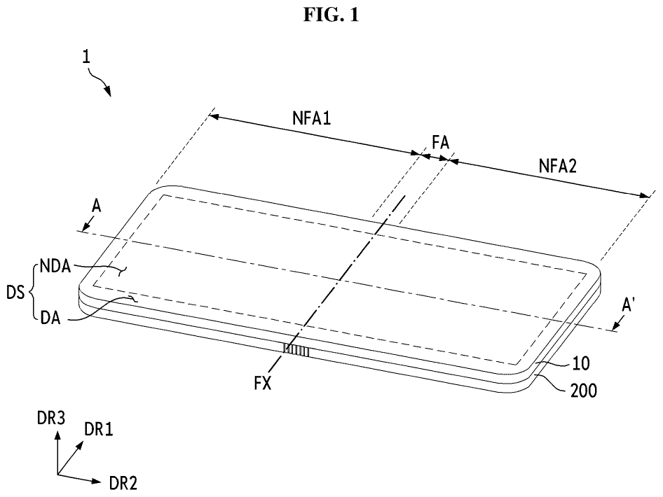

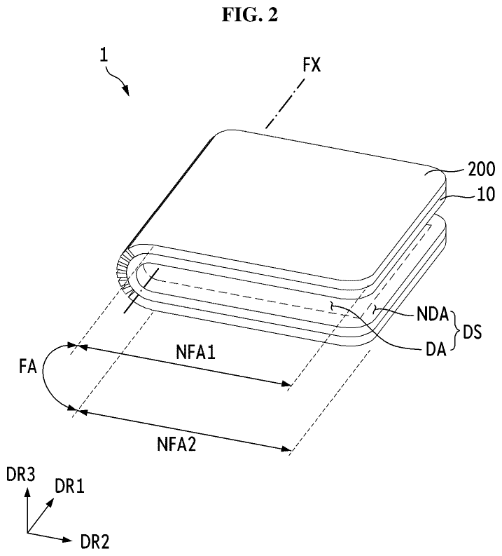

FIG. 1 is a perspective view of a display device according to an embodiment of the present disclosure. FIG. 2 is a perspective view showing the display device according to the embodiment of the present disclosure when it is folded.

According to the embodiment of the present disclosure, the display device 1 is applied to a smartphone. It should be understood, however, that the embodiments of the present disclosure are not limited thereto. For example, the display device 1 according embodiments of the present disclosure may be applied to a mobile phone, a tablet PC, a personal digital assistant (PDA), a portable multimedia player (PMP), a television set, a game machine, a wristwatch-type electronic device, a head-mounted display, a personal computer monitor, a laptop computer, a car navigation system, a car instrument cluster, a digital camera, a camcorder, an outdoor billboard, an electronic billboard, various medical apparatuses, various home appliances such as a refrigerator and a laundry machine, or Internet of things (IoT) devices, in addition to a smart phone. Hereinafter, embodiments of the present disclosure will be described with reference to the accompanying drawings.

In the following description, a first direction DR1, a second direction DR2 and a third direction DR3 are different directions and cross one another. The first direction DR1 may be a width direction, the second direction DR2 may be a length direction, and the third direction DR3 may be a thickness direction. The third direction DR3 may be a front direction facing upward in the drawings. The surface of an element that faces in the front direction may be referred to as the front surface, while the opposite surface of the element that faces in the rear direction may be referred to as the rear surface. It is to be noted that the directions are relative and are not limited by those described above.

Referring to FIGS. 1 and 2, the display device 1 according to the embodiment may have a rectangular or square shape when viewed from the top. According to the embodiment of the present disclosure, the display device 1 may have a rectangular shape with sharp corners or a rectangular shape with rounded corners when viewed from the top. The display device 1 may include two shorter sides extended in the first direction DR1 and two longer sides extended in the second direction DR2 when viewed from the top. However, the present disclosure is not limited thereto. The display device 1 may have various shapes.

The display device 1 may include a front surface and a rear surface. The display device 1 may further include at least one side surface between the front and rear surfaces.

The display device 1 includes at least one display surface DS. According to the embodiment of the present disclosure, the display surface DS may be the front surface of the display device 1. The display surface DS may be extended across a folding area FA and non-folding areas NFA1 and NFA2 described below. In some embodiments, both the front surface and the rear surface of the display device 1 may be display surfaces DS. In some embodiments, the plurality of display surfaces DS may be two or more surfaces such as the front surface, the back surface and the side surfaces of the display device 1.

The display surface DS may include a display area DA and a non-display area NDA.

The display area DA is an area for displaying images. The shape of the display area DA may conform to the shape of the display device 1 when viewed from the top. For example, when the display device 1 is rectangular when viewed from the top, the display area DA may also be rectangular.

The display area DA may include a plurality of pixels to display images. The plurality of pixels may be arranged in a matrix pattern. The plurality of pixels may be, but is not limited to, a rectangle, a diamond, or a square when viewed from the top. For example, the plurality of pixels may be a quadrangle other than a rectangle, a diamond or a rectangle, a polygon other than a quadrangle, a circle, or an ellipse when viewed from the top.

The non-display area NDA may not include pixels and thus may not display images. The non-display area NDA may be disposed around the display area DA. The non-display area NDA may be disposed to surround the display area DA as shown in FIG. 1, but the present disclosure is not limited thereto. In some embodiments, the display area DA may be partially surrounded by the non-display area NDA. In some embodiments, the display area DA may have a rectangular shape, and the non-display area NDA may be located along the four sides of the display area DA. However, the present disclosure is not limited thereto.

According to the embodiment of the present disclosure, the display device 1 may be a foldable device. The display device 1 can be folded or unfolded. The term “folded” may encompass “bent.” Specifically, a portion of the display device 1 may overlap another portion, a portion thereof may be bent and inclined with respect to another portion, or the entire display device 1 may be unfolded flat. According to the embodiment of the present disclosure, a portion of the display device 1 may be folded at an angle approximately greater than 0° and less than 180° relative to another part, or may be unfolded flat to form an inclination of approximately 180°. Terms such as “about” or “approximately” may reflect amounts, sizes, orientations, or layouts that vary only in a small relative manner, and/or in a way that does not significantly alter the operation, functionality, or structure of certain elements. For example, a range from “about 0.1 to about 1” may encompass a range such as a 0%-5% deviation around 0.1 and a 0% to 5% deviation around 1, especially if such deviation maintains the same effect as the listed range.

The display device 1 may be infolded and/or outfolded. When the display device 1 is infolded, a portion of the display surface DS of the display device 1 may face another portion of the display surface DS. When the display device 1 is outfolded, a portion of the display surface DS of the display device 1 may not face another portion. When the display device 1 is outfolded, a portion of the opposite surface of the display surface DS of the display device 1 may face another portion of the opposite side surface of the display surface DS. According to the embodiment of the present disclosure, the display device 1 is infolded, but the present disclosure is not limited thereto.

The display device 1 may have a folded state or an unfolded state. The folded state includes a state in which the display device 1 is bent. Specifically, the folded state may refer to a state in which a portion of the display device 1 is bent to form an inclination relative to another portion, while the unfolded state may refer to a state in which a portion of the display device 1 is located on the same plane with another portion. Alternatively, the folding state may refer to a state in which the angle between a portion of the display device 1 and another portion is between approximately 0° and 180°, and/or between approximately 180° and 360°, and the unfolding state may refer to a state in which the angle between a portion of the display device 1 and another part is approximately 180°. Herein, the portion and another portion may be non-folding areas NFA1 and NFA2 described below, respectively.

The display device 1 may be divided into the folding area FA and non-folding areas NFA1 and NFA2. The folding area FA is folded or bent as the display device 1 is folded. The non-folding areas NFA1 and NFA2 are not folded or bent. The non-folding areas NFA1 and NFA2 may include a first non-folding area NFA1 and a second non-folding area NFA2. According to the embodiment of the present disclosure, the first non-folding area NFA1 and the second non-folding area NFA2 are arranged in the second direction DR2, and the folding area FA may be disposed between the first non-folding area NFA1 and the second non-folding area NFA2. According to this embodiment, one folding area FA and two non-folding areas NFA1 and NFA2 are defined in the display device 1, but the present disclosure is not limited thereto. In some embodiments, a plurality of folding areas FA and non-folding areas NFA1 and NFA2 may be defined in the display device 1.

The display device 1 may be folded or unfolded along on a folding axis FX. The folding axis FX may overlap the folding area FA in the thickness direction. According to the embodiment of the present disclosure, the display device 1 can be folded or unfolded on the folding axis FX extended in the first direction DR1, but the present disclosure is not limited thereto. The folding axis FX may include at least one rotation axis. Specifically, the display device 1 can be folded or unfolded with at least one center of curvature.

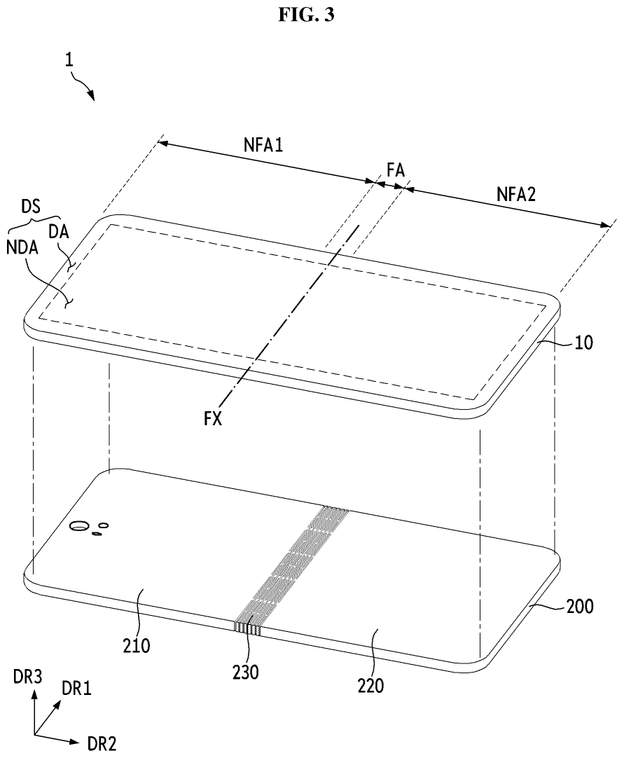

Hereinafter, the display device 1 according to the embodiment will be described in detail with reference to FIGS. 3 to 7.

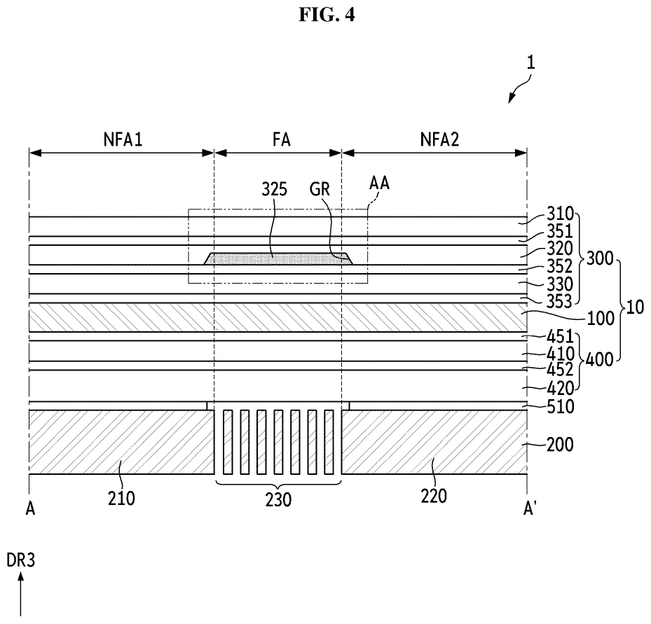

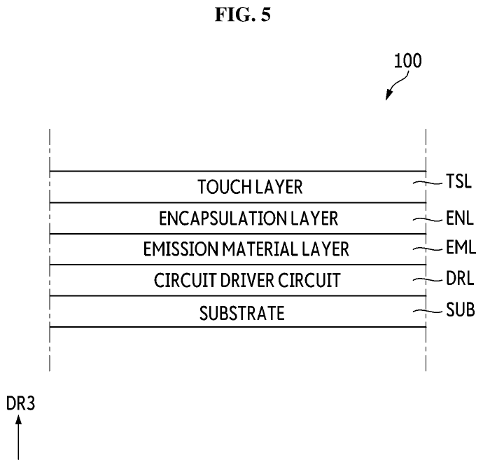

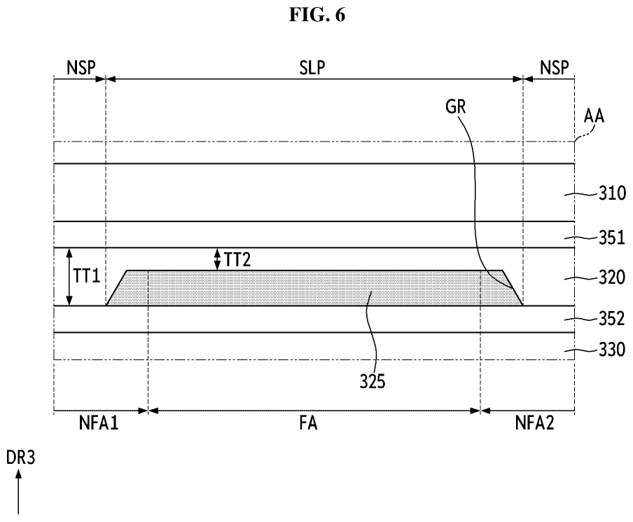

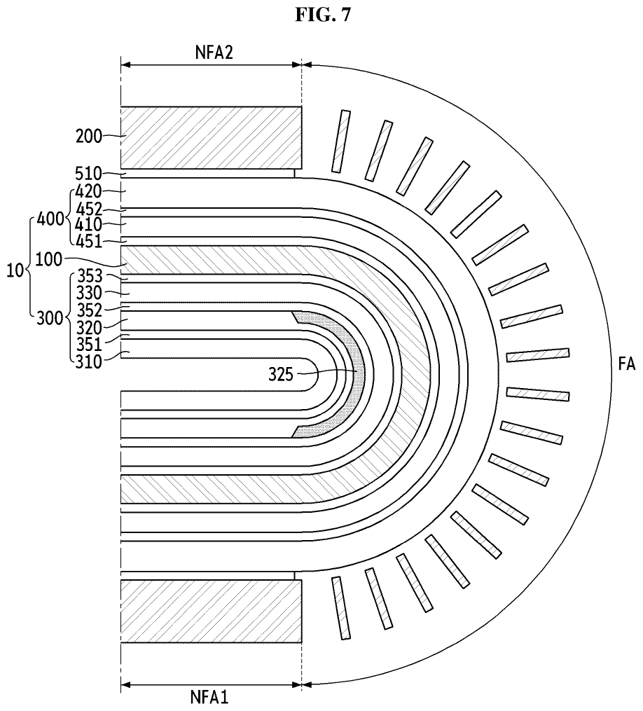

FIG. 3 is an exploded perspective view of the display device shown in FIG. 1. FIG. 4 is a cross-sectional view of the display device, taken along line A-A′ of FIG. 1. FIG. 5 is a cross-sectional view of a display panel according to an embodiment of the present disclosure. FIG. 6 is an enlarged view of area AA of FIG. 4. FIG. 7 is a cross-sectional view schematically showing the display device according to the embodiment when it is folded.

Referring to FIGS. 1 to 7, the display module 10 may be disposed on the front surface of a metal plate 200. The front surface of the display module 10 may form the front surface of the display device 1.

The display module 10 has flexibility. The display module 10 may be extended across the first non-folding area NFA1, the folding area FA and the second non-folding area NFA2, and may be folded on the folding axis FX.

Referring to FIG. 4, the display module 10 may include a display panel 100, a front stack structure 300, and a rear stack structure 400.

The display module 10 may include the display panel 100, the front stack structure 300 stacked on a front side (i.e., an upper surface) of the display panel 100, and the rear stack structure 400 stacked on a rear side (i.e., a lower surface) of the display panel 100. The front side of the display panel 100 may refer to the side where the display panel 100 displays images, and the rear side may refer to the opposite side to the front side.

The display panel 100 displays images and may include a self-luminous display panel such as an organic light-emitting display panel (OLED), an inorganic light-emitting display panel (inorganic EL), a quantum-dot light-emitting display panel (QED), a micro LED display panel (micro-LED), a nano LED display panel (nano-LED), a plasma display panel (PDP), a field emission display panel (FED) and a cathode ray display panel (CRT), as well as a light-receiving display panel such as a liquid-crystal display panel (LCD) and an electrophoretic display panel (EPD). In the following description, the organic light-emitting display panel will be described as an example of the display panel 100, and the organic light-emitting display panel will be simply referred to as the display panel 100 unless specifically stated otherwise. However, the present disclosure is not limited to an organic light-emitting display panel.

The display panel 100 may further include a touch member. The touch member may be implemented as a panel or film separated from the display panel 100 to be attached on the display panel 100 or may be implemented in the form of a touch layer inside the display panel 100. Although the touch member is provided inside the display panel 100 to be included in the display panel 100 in the following description, the present disclosure is not limited thereto.

Referring to FIGS. 4 and 5, the display panel 100 may include a substrate SUB, a circuit driving layer DRL on the substrate SUB, an emissive layer EML on the circuit driving layer DRL, an encapsulation layer ENL on the emissive layer EML, and a touch layer TSL on the encapsulation layer ENL.

The substrate SUB may be a flexible substrate including a flexible polymer material such as polyimide. Accordingly, the display panel 100 may be curved, bent, folded, or rolled. In some embodiments, the substrate SUB may include a plurality of sub-substrates overlapping in the thickness direction with a barrier layer therebetween. In such case, each of the sub-substrates may be a flexible substrate.

The circuit-driving layer DRL may be disposed on the substrate SUB. The circuit-driving layer DRL may include a circuit for driving an emissive layer EML of each pixel. The circuit-driving layer DRL may include a plurality of thin-film transistors.

The emissive layer EML may be disposed on the circuit-driving layer DRL. The emissive layer EML may include an organic emitting layer. The emissive layer EML may emit light with various values of luminance depending on driving signals transmitted from the circuit-driving layer DRL.

The encapsulation layer ENL may be disposed on the emissive layer EML. The encapsulation layer ENL may include an inorganic film or a stack of an inorganic film and an organic film.

The touch layer TSL may be disposed on the encapsulation layer ENL. The touch layer TSL may sense a touch input and may perform the functions of the touch member. The touch layer TSL may include a plurality of sensing regions and sensing electrodes.

Referring to FIG. 4, the front stack structure 300 is disposed in front of the display panel 100. For example, the front stack structure 300 may be disposed on the front side of the display panel 100. The front stack structure 300 may include a polarizing member 330, a cover window 320 and a cover window protection layer 310 sequentially stacked on one another from the display panel DP toward a front side of the display module 10.

The polarizing member 330 polarizes the light passing therethrough. The polarizing member 330 can reduce the reflection of external light. In an embodiment, the polarizing member 330 may be a polarizing film. The polarizing film may include protective substrates and a polarizing layer sandwiched between the protective substrates. The polarizing layer may include a polyvinyl alcohol film. The polarizing layer may be stretched in a direction. The direction in which the polarizing layer may be stretched may be an absorption axis, while the direction perpendicular thereto may be a transmission axis. The protective substrates may be disposed on one side and the other side of the polarizing layer, respectively. The protective substrates may be made of, but is not limited to, a cellulose resin such as triacetyl cellulose and a polyester resin.

The cover window 320 may be disposed in front of the polarizing member 330. For example, the cover window 320 may be disposed on an upper surface of the polarizing member 330. The cover window 320 serves to protect the display panel 100. The cover window 320 may be made of a transparent material. The cover window 320 may include, for example, glass or plastic.

When the cover window 320 includes glass, the glass may be ultra-thin glass (UTG) or thin glass. When the glass is formed as ultra-thin glass or thin glass, it may have flexibility and may be curved, bent, folded or rolled. The thickness of the glass may be, for example, in the range of 10 μm to 300 μm, and specifically 30 μm to 80 μm. The glass of the cover window 320 may include soda lime glass, alkali alumino silicate glass, borosilicate glass, or lithium alumina silicate glass. The glass of the cover window 320 may include chemically or thermally tempered glass to have a high strength. The chemical tempering may be carried out via an ion exchange process in an alkali salt. The ion exchange process may be performed two or more times.

Referring to FIG. 6, the cover window 320 may include a slim portion SLP and a flat portion NSP. The flat portion NSP may overlap the non-folding areas NFA1 and NFA2 of the display device 1, where the cover window 320 is not folded. The slim portion SLP may overlap the folding area FA of the display device 1, where the cover window 320 is folded. The flat portion NSP may form the thickness TT1 of the overall cover window 320, and the thickness TT2 of the slim portion SLP may be smaller than the thickness TT1 of the flat portion NSP. For example, the thickness TT1 of the flat portion NSP of the cover window 320 may range from 60 to 80 μm.

The slim portion SLP may be extended lengthwise in the first direction DR1 along the folding area FA. The slim portion SLP may include a groove GR formed at the lower surface of the cover window 320. For example, the groove GR may correspond to a recessed region that is recessed from the lower surface of the cover window 320 toward the upper surface.

As the cover window 320 includes the slim portion SLP that overlaps the folding area FA of the display device 1, the strain applied to the cover window 320 when the cover window 320 is folded can be reduced, thereby preventing cracks in the cover window 320.

According to the embodiment, the cover window 320 may include a resin layer 325 disposed in the groove GR of the slim portion SLP. The resin layer 325 may be disposed between the cover window 320 and a second front coupling member 352 and may be in contact with the second front coupling member 352. For example, the resin layer 325 may be disposed on the lower surface of the cover window 320 adjacent to the display panel 100 among the surfaces of the cover window 320. The resin layer 325 may be disposed inside the groove GR of the slim portion SLP.

The resin layer 325 can reduce the strain applied to the cover window 320 when the cover window 320 is folded, thereby preventing cracks from occurring in the cover window 320. The resin layer 325 may include a material that can be flexibly folded and unfolded when the cover window 320 is folded. For example, the resin layer 325 may include at least one resin material selected from the group consisting of acrylic, epoxy, silicone, urethane, and siloxane. The resin layer 325 may have a refractive index substantially equal to a refractive index of the cover window 320 in order to prevent the light output from the display panel 100 from changing its light path at the interface between the cover window 320 and the resin layer 325. For example, the difference between the refractive index of the resin layer 325 and the refractive index of the cover window 320 may be equal to or less than 0.009. Terms such as “same,” “equal,” “planar,” or “coplanar,” as used herein encompass near identicality including variations that may occur, for example, due to manufacturing processes. The term “substantially” may be used herein to emphasize this meaning, unless the context or other statements indicate otherwise.

Even though the resin layer 325 contains the resin material described above, cracks may occur due to the strain applied to the cover window 320 during folding and unfolding depending on the modulus. According to the embodiment where the groove GR of the cover window 320 is located at the lower surface of the cover window 320, the resin layer 325 may have a modulus in the range of 20 MPa to 2 Gpa at the room temperature of 25° C. With a modulus of the resin layer 325 equal to or greater than 20 Mpa at the room temperature of 25° C., it is possible to prevent the folding and unfolding operations of the cover window 320 (e.g., the display device 1 including the cover window 320) from becoming impossible due to an increase in repulsive force during the folding and unfolding operations. For example, when the modulus of the resin layer 325 is 20 Mpa or higher at the room temperature of 25° C., the folding and unfolding operations of the cover window 320 (e.g., the display device 1 that includes the cover window 320) can be maintained. Increased repulsive forces during these operations do not render the folding and unfolding operations unworkable. With a modulus of the resin layer 325 equal to or less than 2 GPa at the room temperature of 25° C., it is possible to prevent the occurrence of cracks in the resin layer 325 due to an increase in strain applied to the resin layer 325 during the folding and unfolding operations. For example, when the modulus of the resin layer 325 is 2 Gpa or lower at the room temperature of 25° C., cracks in the resin layer 325 can be avoided, even when increased strain is applied to it during the folding and unfolding operations.

The resin layer 325 may have a modulus in the range of 30 Mpa to 1 Gpa at the low temperature of −20° C. With a modulus of the resin layer 325 equal to or greater than 30 Mpa at the low temperature of −20° C., it is possible to prevent the folding and unfolding operations of the cover window 320 (e.g., the display device 1 including the cover window 320) from becoming impossible due to an increase in repulsive force during the folding and unfolding operations. For example, when the modulus of the resin layer 325 is 20 Mpa or higher at a temperature of −20° C., the folding and unfolding operations of the cover window 320 (e.g., the display device 1 that includes the cover window 320) can be maintained. Increased repulsive forces during these operations do not render the folding and unfolding operations unworkable. With a modulus of the resin layer 325 equal to or less than 1 GPa at the low temperature of −20° C., it is possible to prevent the occurrence of cracks in the resin layer 325 due to an increase in strain applied to the resin layer 325 during the folding and unfolding operations. For example, when the modulus of the resin layer 325 is 1 Gpa or lower at the temperature of −20° C., cracks in the resin layer 325 can be avoided, even when increased strain is applied to it during the folding and unfolding operations.

Referring back to FIG. 4, a cover window protection layer 310 may be disposed in front of the cover window 320. For example, the cover window protection layer 310 may be disposed on an upper surface of the cover window 320. The cover window protection layer 310 may perform at least one of functions of anti-scattering when the cover window 320 is broken, shock absorption, anti-scratch, anti-fingerprint, and anti-glare. The cover window protection layer 310 may include a transparent polymer film. The transparent polymeric film may include at least one selected from the group consisting of: polyethylene terephthalate (PET), polyethylene naphthalate (PEN), polyether sulfone (PES), polyimide (PI), polyarylate (PAR), polycarbonate (PC), polymethyl methacrylate (PMMA) and cyclo olefin copolymer (COC) resin.

The front stack structure 300 may include front coupling members 351, 352 and 353 each coupling between adjacent ones of the elements stacked on one another. For example, the first front coupling member 351 may be disposed between the cover window 320 and the cover window protection layer 310 to couple them together, the second front coupling member 352 may be disposed between the cover window 320 and the polarizing member 330 to couple them together, and the third front coupling member 353 may be disposed between the polarizing member 330 and the display panel 100 to couple them together. For example, the front coupling members 351, 352 and 353 are for attaching the layers to a surface of the display panel 100. The first front coupling member 351 may be a polymer film layer for attaching the cover window protection layer 310, the second front coupling member 352 may be a window coupling member for attaching the cover window 320, and the third front coupling member 353 may be a polarizing member coupling member for attaching the polarizing member 330. The front coupling members 351, 352 and 353 may be all optically transparent.

The rear stack structure 400 is disposed at the back of the display panel 100. The rear stack structure 400 may include a polymer film layer 410 and a barrier member 420 disposed on the rear side of the display panel 100.

The polymer film layer 410 may include a polymer film. The polymer film layer 410 may include, for example, polyimide (PI), polyethylene terephthalate (PET), polycarbonate (PC), polyethylene (PE), polypropylene (PP), polysulfone (PSF), polymethyl methacrylate (PMMA), triacetyl cellulose (TAC), or cycloolefin polymer (COP). The polymer film layer 410 may include a functional layer which may be disposed on at least one surface of the polymer film layer 410. The functional layer may include, e.g., a light-absorbing layer. The light-absorbing layer may include a light-absorbing material such as a black pigment and dye. The light-absorbing layer may be formed on a polymer film by coating or printing a black ink.

The barrier member 420 may be disposed on the rear side of the polymer film layer 410. The barrier member 420 can prevent particles from being introduced into the display module 10 from the outside. The barrier member 420 may be made of an elastic material so that its length can be elastically varied according to folding and unfolding operations of the display device 1.

The rear stack structure 400 may include rear coupling members 451 and 452 that couple adjacent ones of the elements stacked on one another. For example, the first rear coupling member 451 may be disposed between the display panel 100 and the polymer film layer 410 to couple them together, and the second rear coupling member 452 may be disposed between the polymer film layer 410 and the barrier member 420 to couple them together. For example, the rear coupling member 451 and 452 may be attached to the rear surface of the display panel 100. The first rear coupling member 451 may be a polymer film layer coupling member that attaches the polymer film layer 410, and the second rear coupling member 452 may be a barrier coupling member that attaches the barrier member 420.

The metal plate 200 may be disposed at the back of the display module 10.

Referring to FIGS. 1 to 4, the display device 1 according to the embodiment may include the metal plate 200 disposed at the back of the display module 10.

The metal plate 200 may be disposed on the rear surface of the barrier member 420. The metal plate 200 may overlap the first non-folding area NFA1, the folding area FA, and the second non-folding area NFA2. The metal plate 200 may be flexible and may be folded on the folding axis FX. The metal plate 200 may include a pattern for forming a plurality of openings and thus may be at least partially elastic.

The metal plate 200 may have, but is not limited to, a rectangular shape that is elongated in the second direction DR2. According to the embodiment of the present disclosure, the metal plate 200 may include front and rear surfaces that are parallel to the plane formed by the first direction DR1 and the second direction DR2 intersecting each other, and side surfaces that are extended in the third direction DR3 between the front and rear surfaces.

The metal plate 200 may include stainless steel. The stainless steel may include, for example, at least one of iron, chromium, carbon, nickel, silicon, manganese and molybdenum, and alloys thereof. According to an embodiment of the present disclosure, the metal plate 200 may be made of austenitic stainless steel.

According to the embodiment of the present disclosure, the metal plate 200 may include a first plate 210, a second plate 220, and a connector 230.

The first plate 210 and the second plate 220 are arranged in the second direction DR2. The first plate 210 and the second plate 220 may be arranged symmetrically with respect to the folding axis FX or the folding area FA. According to the embodiment of the present disclosure, the first plate 210 may be in line with the first non-folding area NFA1, and the second plate 220 may be in line with the second non-folding area NFA2. Accordingly, the first plate 210 and the second plate 220 may remain flat regardless of the folding of the display device 1. The first plate 210 and the second plate 220 may have, but is not limited to, a rectangular shape when viewed from the top. According to the embodiment of the present disclosure, the first plate 210 and the second plate 220 may not stretch but maintain their length or size when the display device 1 is folded.

The connector 230 may be disposed between the first plate 210 and the second plate 220. The connector 230 may be located in the folding area FA. The connector 230 may be in line with the folding axis FX in the thickness direction. The folding axis FX may extend in the first direction DR1. The connector 230 has flexibility. The connector 230 may be stretched or compressed by folding or unfolding of the metal plate 200. The connector 230 may be more elastic than the first plate 210 and/or the second plate 220. The connector 230 may reduce tensile or compressive stress caused by bending of the metal plate 200. The connector 230 may include a pattern for forming a plurality of openings.

The metal plate 200 described above may be coupled on the rear side of the display module 10 by means of a first coupling member 510. The first coupling member 510 may be disposed between the barrier member 420 and the metal plate 200 to couple them together.

Hereinafter, a display device 1 according to another embodiment of the present disclosure will be described with reference to other drawings.

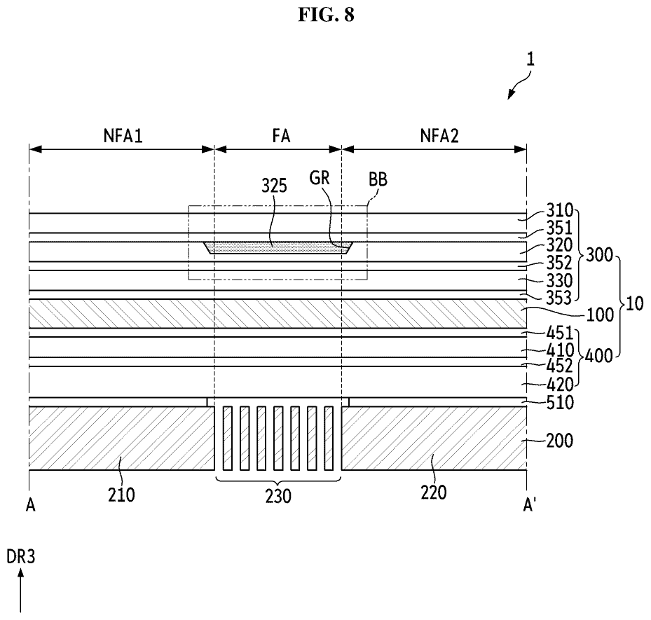

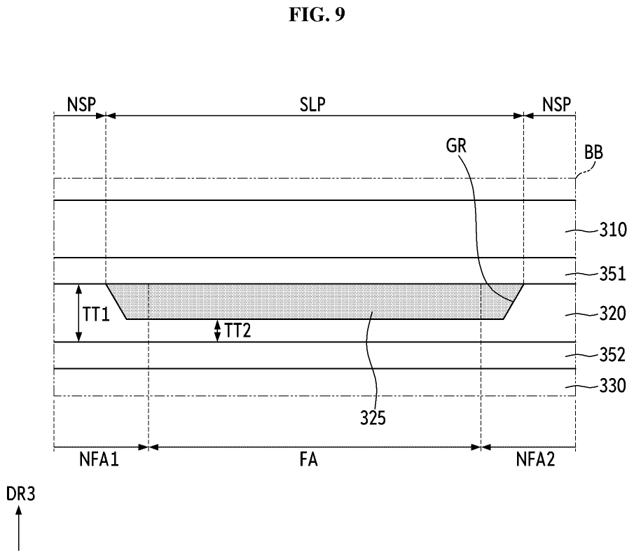

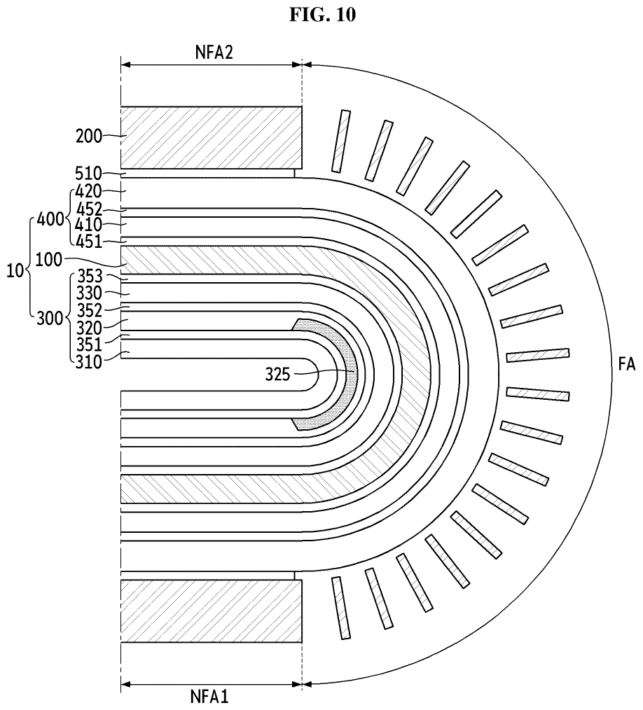

FIG. 8 is a cross-sectional view schematically showing a display device according to an embodiment. FIG. 9 is an enlarged view of area BB of FIG. 8. FIG. 10 is a cross-sectional view schematically showing the display device according to the embodiment when it is folded.

The display device 1 according to the embodiment of FIGS. 8 to 10 is different from the above-described embodiment in that a groove GR of a slim portion SLP of a cover window 320 is located at the upper surface of the cover window 320. The following description will focus on the differences and the redundant description will be omitted.

The cover window 320 may include a slim portion SLP and a flat portion NSP. The flat portion NSP may overlap the non-folding areas NFA1 and NFA2 of the display device 1, where the cover window 320 is not folded. The slim portion SLP may overlap the folding area FA of the display device 1, where the cover window 320 is folded. The flat portion NSP may form the thickness of the overall cover window 320, and the thickness of the slim portion SLP may be smaller than the thickness of the flat portion NSP. The slim portion SLP may be extended lengthwise in the first direction DR1 along the folding area FA. The groove GR of the slim portion SLP may be located at the upper surface of the cover window 320 that is distant from the display panel 100 among the surfaces of the cover window 320. The groove GR of the slim portion SLP may correspond to a recessed region that is recessed from the upper surface of the cover window 320 toward the lower surface.

As the cover window 320 includes the slim portion SLP that overlaps the folding area FA of the display device 1, the strain applied to the cover window 320 when the cover window 320 is folded can be reduced, thereby preventing cracks in the cover window 320.

According to the embodiment, the cover window 320 may include a resin layer 325 disposed in the groove GR of the slim portion SLP. The resin layer 325 may be disposed between the cover window 320 and a first front coupling member 351 and may be in contact with the first front coupling member 351. The resin layer 325 may be disposed inside the groove GR of the slim portion SLP. The resin layer 325 can reduce the strain applied to the cover window 320 when the cover window 320 is folded, thereby preventing cracks from occurring in the cover window 320.

According to the embodiment where the slim portion SLP of the cover window 320 includes a groove which is located at the upper surface of the cover window 320, the resin layer 325 may have a modulus in the range of 10 Mpa to 2 Gpa at the room temperature of 25° C. With a modulus of the resin layer 325 equal to or greater than 10 Mpa at the room temperature of 25° C., it is possible to prevent the folding and unfolding operations of the cover window 320 (e.g., the display device 1 including the cover window 320) from becoming impossible due to an increase in repulsive force during the folding and unfolding operations. For example, when the modulus of the resin layer 325 is 10 Mpa or higher at the room temperature of 25° C., the folding and unfolding operations of the cover window 320 (e.g., the display device 1 that includes the cover window 320) can be maintained. Increased repulsive forces during these operations do not render the folding and unfolding operations unworkable. With a modulus of the resin layer 325 equal to or less than 2 GPa at the room temperature of 25° C., it is possible to prevent the occurrence of cracks in the resin layer 325 due to an increase in strain applied to the resin layer 325 during the folding and unfolding operations. For example, when the modulus of the resin layer 325 is 2 Gpa or lower at the room temperature of 25° C., cracks in the resin layer 325 can be avoided, even when increased strain is applied to it during the folding and unfolding operations.

The resin layer 325 may have a modulus in the range of 30 Mpa to 1 Gpa at the low temperature of −20° C. With a modulus of the resin layer 325 equal to or greater than 30 Mpa at the low temperature of −20° C., it is possible to prevent the folding and unfolding operations of the cover window 320 (e.g., the display device 1 including the cover window 320) from becoming impossible due to an increase in repulsive force during the folding and unfolding operations. For example, when the modulus of the resin layer 325 is 30 Mpa or higher at a temperature of −20° C., the folding and unfolding operations of the cover window 320 (e.g., the display device 1 that includes the cover window 320) can be maintained. Increased repulsive forces during these operations do not render the folding and unfolding operations unworkable. With a modulus of the resin layer 325 equal to or less than 1 GPa at the low temperature of −20° C., it is possible to prevent the occurrence of cracks in the resin layer 325 due to an increase in strain applied to the resin layer 325 during the folding and unfolding operations. For example, when the modulus of the resin layer 325 is 1 Gpa or lower at the temperature of −20° C., cracks in the resin layer 325 can be avoided, even when increased strain is applied to it during the folding and unfolding operations.

Table 1 below shows the results of a folding test performed at the room temperature of 25° C. for different locations of the slim portion SLP of the cover window 320. In Table 1, the folding test was conducted by changing the modulus of the resin layer 325 disposed in the groove GR of the slim portion SLP, which is located at the lower surface of the cover window 320 as in the example shown in FIG. 4 or at the upper surface of the cover window 320 as in the example shown in FIG. 8. The symbol X represents that the cover window failed to be folded, or a crack occurred in the resin layer and accordingly the cover window protection layer thereon is delaminated. The symbol O represents that there is no defect.

TABLE 1

| | | |
|---|---|---|
| Modulus of Resin | Groove at Lower | Groove at Upper |
| Layer | Surface | Surface |

| | | | |
|---|---|---|---|
| 50 | kPa | X | X |
| 100 | kPa | X | X |
| 500 | kPa | X | X |
| 1 | Mpa | X | X |
| 5 | Mpa | X | X |
| 10 | Mpa | X | ◯ |
| 20 | Mpa | ◯ | ◯ |
| 30 | Mpa | ◯ | ◯ |
| 40 | Mpa | ◯ | ◯ |
| 50 | Mpa | ◯ | ◯ |
| 1 | Gpa | ◯ | ◯ |
| 2 | Gpa | ◯ | ◯ |
| 3 | Gpa | X | X |

Referring to Table 1 above, when the modulus of the slim portion SLP was less than 20 Mpa, the repulsive force against folding was too large for the cover window to be folded. When the modulus of the slim portion SLP exceeded 2 Gpa, cracks occurred in the slim portion SLP during folding and accordingly the cover window protection layer 310 disposed thereon was delaminated. On the other hand, in the structure where the slim portion SLP of the cover window 320 includes a groove which is located at the lower surface of the cover window 320, the folding test results were normal with the modulus of the slim portion SLP in the range of 20 Mpa to 2 Gpa.

Table 2 below shows the results of a folding test performed at the low temperature of −20° C. for different locations of the slim portion SLP of the cover window 320. In Table 2, the folding test was conducted by changing the modulus of the resin layer 325 disposed in a groove of the slim portion SLP, which is located at the lower surface of the cover window 320 as in the example shown in FIG. 4 or at the upper surface of the cover window 320 as in the example shown in FIG. 8. The symbol X represents that the cover window failed to be folded, or a crack occurred in the resin layer and accordingly the cover window protection layer thereon is delaminated. The symbol O represents that there is no defect.

TABLE 2

| | | |
|---|---|---|
| Modulus of Resin | Groove at Lower | Groove at Upper |
| Layer | Surface | Surface |

| | | | |
|---|---|---|---|
| 50 | kPa | X | X |
| 100 | kPa | X | X |
| 500 | kPa | X | X |
| 1 | Mpa | X | X |
| 5 | Mpa | X | X |
| 10 | Mpa | X | X |
| 20 | Mpa | X | X |
| 30 | Mpa | ◯ | ◯ |
| 40 | Mpa | ◯ | ◯ |
| 50 | Mpa | ◯ | ◯ |
| 1 | Gpa | ◯ | ◯ |
| 2 | Gpa | X | X |

Referring to Table 2 above, when the modulus of the slim portion SLP was less than 30 Mpa, the repulsive force against folding was too large for the cover window to be folded. When the modulus of the slim portion SLP exceeded 1 Gpa, cracks occurred in the slim portion SLP during folding and accordingly the cover window protection layer 310 disposed thereon was delaminated. On the other hand, in the structure where the slim portion SLP of the cover window 320 includes a groove which is located at the lower surface of the cover window 320, the folding test results were normal with the modulus of the slim portion SLP in the range of 30 Mpa to 1 Gpa.

It can be seen from the results of Table 1 and Table 2 above that when the slim portion SLP of the cover window 320 includes a groove which is located at the lower surface of the cover window 320, the resin layer 325 has a modulus in the range of 20 Mpa to 2 Gpa at the room temperature of 25° C. and a modulus in the range of 30 Mpa to 1 Gpa at the low temperature of −20° C., so that the display device 10 can be folded more reliably. It can be seen that when the slim portion SLP of the cover window 320 includes a groove which is located at the upper surface of the cover window 320, the resin layer 325 has a modulus in the range of 10 Mpa to 2 Gpa at the room temperature of 25° C. and a modulus in the range of 30 Mpa to 1 GPa at the low temperature of −20° C., so that the display device 10 can be folded more reliably.

Table 3 below shows the strains applied to the cover window, the protection layer coupling member and the cover window protection layer measured at the room temperature of 25° C. and the low temperature of −20° C. when a display device having the cover window without a slim portion, a display device having a cover window with a slim portion having a groove located at the lower surface, and a display device having a cover window with a slim portion having a groove located at the upper surface are folded. A resin layer having the modulus of 20 MPa at room temperature and the modulus of 30 MPa at the low temperature of −20° C. was disposed in the slim portion.

Table 3 shows the buckling resistance index (BRI). The buckling resistance index shows the probability that a film (e.g., the cover window protection layer) adhered to the cover glass will fall off. The larger the index is, the more reliably the film is adhered, and the smaller the index is, the more easily the film is detached. For example, a higher index indicates stronger adhesion of the film, while a lower index signifies easier detachment.

The buckling resistance index can be calculated using Equations 1 and 2 below. For example, the critical buckling stress ∂_{c} may be obtained by Equation 1, and the critical buckling stress may be divided by the compressive stress θ_{f} applied to the film during folding, and the buckling resistance index (BRI) may be calculated by Equation 2:

$${σ}_{c} = \sqrt{\frac{{T}_{f}}{3 {T}_{a}} {E}_{f} {E}_{a}} \qquad [ Equation 1 ]$$

where T_{f} denotes the thickness of the film, Tₐ denotes the thickness of the adhesive layer (e.g., the protection layer coupling member), E_{F} denotes the modulus of the film, and Eₐ denotes the modulus of the adhesive layer.

$$B R I = \frac{{σ}_{c}}{{σ}_{f}} \qquad [ Equation 2 ]$$

TABLE 3

| | | 25° C. | | | −20° C. | | |
|---|---|---|---|---|---|---|---|
| | | Modulus of Resin Layer | | | | | |
| | | — | 20 MPa | | — | 30 MPa | |
| | | Structure | | | | | |
| | | | Slim | Slim | | Slim | Slim |
| | | | Portion | Portion | | Portion | Portion |
| | | No Slim | on Lower | on Upper | No Slim | on Lower | on Upper |
| | | Portion | Surface | Surface | Portion | Surface | Surface |
| Strain (%) | Cover | 2.451 | 2.387 | 2.039 | 2.03 | 2.211 | 1.541 |
| for Different | window | | | | | | |
| Layers | protection | | | | | | |
| | layer | | | | | | |
| | Coupling | 2.227 | 2.153 | 1.621 | 1.812 | 1.985 | 1.149 |
| | Member | | | | | | |
| | Cover | 1.111 | 1.041 | 1.011 | 1.071 | 1.06 | 0.973 |
| | Window | | | | | | |

| | | | | | | |
|---|---|---|---|---|---|---|
| Buckling Resistance | 2.366 | 2.444 | 1.853 | 2.518 | 2.6 | 1.738 |
| Index (BRI) | | | | | | |

Referring to Table 3 above, it can be seen that the display device having the groove of the slim portion located at the lower surface of the cover window exhibited an increased buckling resistance index during folding compared to the display device not having the slim portion at the room temperature of 25° C. and the low temperature of −20° C.

It can be seen from these results that the display device in which the groove of the slim portion is located at the lower surface of the cover window and the resin layer disposed in the slim portion has the modulus of 20 MPa at room temperature of 25° C. and the modulus of 30 MPa at the low temperature of −20° C. can reduce the possibility of buckling during folding because the window protection layer is relatively firmly attached to the cover window.

It can be seen that the display device having the groove of the slim portion located at the upper surface of the cover window can reduce the strain applied to the cover window and the cover window protection layer during folding compared to the display device without the slim portion.

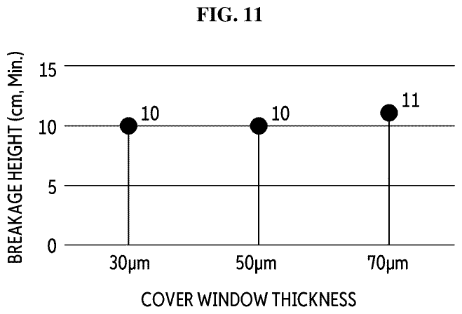

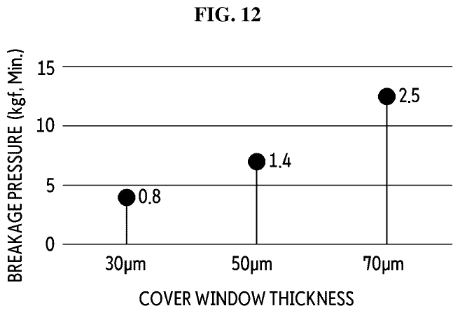

FIG. 11 is a graph showing results of a pen drop test of cover windows. FIG. 12 is a graph showing results of a pen pressure test of cover windows.

The pen drop test was conducted by dropping a pen with the diameter of 0.3 mm and the weight of 5.6 g onto the surface of cover windows fixed on a stone plate and checking the height at which the surface of the cover windows broke. The drop height of the pen gradually was increased at the rate of 1 cm per minute, and the height at which the breakage occurred was determined as the breakage height.

The pen pressure test was conducted by increasing the pressure at the rate of 1 kgf per minute on the surface of the cover windows using the same pen used in the pen drop test, and the pressure at which breakage occurred was determined as the breaking pressure (force).

Referring to FIG. 11, the breakage height of the cover window having the thickness of 70 μm was increased compared to the cover windows having the thicknesses of 30 μm and 50 μm.

Referring to FIG. 12, the breakage pressure (force) was increased as the thickness of the cover window was increased to 30 μm, 50 μm, and 70 μm.

It can be seen from the results that the breakage characteristics were improved when the thickness of the cover window increased to approximately 70 μm.

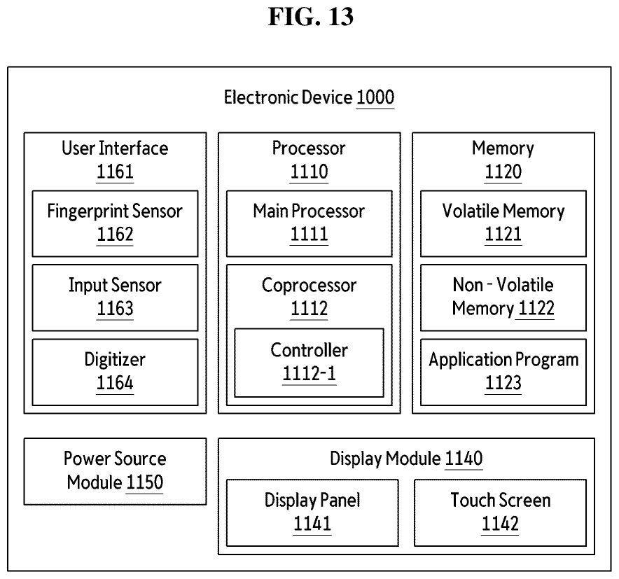

FIG. 13 is a diagram illustrating an electronic device according to an embodiment of the present invention. Referring to FIG. 10, the electronic device 1000 according to one embodiment of the present invention may output various information (e.g., images, text, music, etc.) through a display module 1140, which, for example, may correspond to the display device shown in FIG. 1. When a processor 1110 executes an application stored in a memory 1120, the display module 1140 may provide application information to a user through a display panel 1141.

In some embodiments, the electronic device 1000 may be configured as a smartphone, camera, smart TV, monitor, smartwatch, tablet, automotive display, or AR/VR headset. For example, the electronic device 1000 may be a smartphone including a touch-sensitive display area DA for interaction and a non-display area NDA including sensors and circuits for enhanced functionality. For example, the electronic device 1000 may be a television or monitor including a large display area DA for high-resolution video playback and a non-display area NDA incorporating driving circuits or connectivity modules for external inputs. For example, the electronic device 1000 may be a smartwatch including a display area DA optimized for compact and high-clarity visuals and a non-display area NDA integrating biometric sensors for health monitoring. In some cases, the electronic device 1000 be an AR/VR headset.

In some embodiments, memory 1120 may store information such as software codes for operating an application program 1123. The application program 1123 may include a software designed to execute specific tasks or provide functionality to a user. The application program 1123 may operate under the control of the processor 1110 and utilizes data stored in the memory 1120 to deliver a wide range of features, such as productivity tools, multimedia streaming and playback, file or mail deliveries or communication services. The application program 1123 interacts seamlessly with the user interface 1161 or touch screen 1142, allowing a user to launch, navigate, and utilize the program through user inputs such as touch, tap, gesture, or voice interaction.

Upon user selection of an application via touch screen 1142 or user interface 1161, the processor 1110 may execute the application program 1123 corresponding to the selected application retrieved from the memory 1120 to perform functionalities of the application. For example, when a user selects a camera application by tapping the icon (or a camera application icon) presented on the display panel 1141, the processor 1110 activates a camera module. The processor 1110 may transmit image data corresponding to a captured image acquired through the camera module to the display module 1140. The display module 1140 may display an image corresponding to the captured image through the display panel 1141.

As another example, when a user wishes to make a phone call, the user taps the telephone icon displayed on the display module 1140, the processor 1110 may execute a phone application program stored in the memory 1120. A telephone keypad may be presented on the display panel 1141 for the user to enter a phone number to call.

As another example, the display module 1140 may be installed as a part of a laptop computer, a smart TV, or a tablet (the electronic device 1000), and a user wishes to access a multimedia streaming and playback application, e.g., Netflix®, the user can view Netflix programs by tapping the Netflix icon.

The processor 1110 may include a main processor 1111 and an auxiliary or coprocessor 1112. The main processor 1111 may include a central processing unit (CPU). The main processor 1111 may further include one or more of a graphics processing unit (GPU), a communication processor (CP), and an image signal processor (ISP).

The coprocessor 1112 may include a controller 1112-1. The controller 1112-1 may include an interface conversion circuit and a timing control circuit. The controller 1112-1 may receive an image signal from the main processor 1111, convert the data format of the image signal to match the interface specifications with the display module 1140, and output image data. The controller 1112-1 may output various control signals to drive the display module 1140. For example, the controller 1112-1 may drive the display module 1140 to display the icon on the display screen suitable for selection by a user to cause execution of an application program 1123.

The memory 1120 may store one or more application programs 1123 and various data used by at least one component (for example, the processor 1110 or the user interface 1161) of the electronic device 1000 and input data or output data for commands related thereto. For example, a camera application program, a GPS application program, an augmented reality and virtual reality application program, and other application programs that can be executed by the processor 1110 upon selection of corresponding icons presented on the display screen (or display panel 1141) via the touch screen 1142 or user interface 1161 by the user. In addition, various setting data corresponding to user settings may be stored in the memory 1120. The memory 1120 may include volatile memory 1121 and non-volatile memory 1122.

The display module 1140 may output visual information (images) to the user. The display module 1140 may include the display panel 1141, a gate driver, the source driver, a voltage generation circuit, and a touch screen 1142. The display module 1140 may further include a window, a chassis, and a bracket to protect the display panel 1141. The display module 1140 may include at least a part of the configuration of the display device shown in FIG. 1.

The user interface 1161 serves as the interaction medium between a user and the electronic device 1000. The user interface 1161 may detect an input by a part (e.g., finger) of a user's body or an input by a pen or a mouse, and generate an electric signal or data value corresponding to the input. The user interface 1161 includes the fingerprint sensor 1162, the input sensor 1163, and a digitizer 1164.

The fingerprint sensor 1162 may sense a fingerprint for biometric recognition of the user and may also measure one or more biological signals such as blood pressure, moisture, or body mass.

The input sensor 1163 may sense user interactions including touch, tap, gesture, motion, spoken command, and eye movement. The input sensor 1163 includes optical sensors for image capture, eye tracking, or motion and gesture detection. Optical sensors may be infrared or semiconductor photodetectors. The input sensor 1163 includes audio and acoustic sensors, which may be MEMS microphones for voice recognition or sound-based interaction. The audio and acoustic sensors can be installed as part of the user interface 1161 or embedded in the display panel 1141.

The digitizer 1164 may generate a data value corresponding to coordinate information of input by a pen or a mouse to control movement of an onscreen cursor. The digitizer 1164 may generate the amount of change in electromagnetic due to the input as the data value. The digitizer may detect an input by a passive pen or transmit and receive data with an active pen or a remote.

At least one of the fingerprint sensor 1162, the input sensor 1163, or the digitizer 1164 may be implemented as a sensor layer formed on the top layer of the display panel 1141 through a continuous process with a process of forming elements (for example, the light emitting element, the transistor, and the like) included in the display panel 1141.

In addition, the user interface 1161 may further include, for example, a gesture sensor, a gyro sensor that senses rotational movements, an acceleration sensor to track translational movement, a grip sensor, a pressure sensor, a proximity sensor, a color sensor, an infrared (IR) emitter and camera sensor for tracking gaze direction and eye movements, a temperature sensor, or a light sensor. For example, the gyro sensor, acceleration sensor, and infrared emitter and camera may be particularly suitable for AR/VR headset functions.

The touch screen 1142 includes touch sensors embedded in semiconductor layers of the display panel 1141 to sense pressure applied to the top layer (screen) of the display panel 1141. The touch sensors can be a capacitive or a resistive type. The touch screen 1142 may serve as the primary interface for the user to select and navigate applications, control, and interact with the electronic device 1000.

The display panel 1141 (or display) may include a liquid crystal display panel, an organic light emitting display panel, or an inorganic light emitting display panel, and the type of the display panel 1141 is not particularly limited. The display panel 1141 may be of a rigid type or a flexible type that can be rolled or folded. The display module 1140 may further include a supporter, bracket, heat dissipation member, and the like that support the display panel 1141. The display panel 1141 may include the display unit shown in FIG. 1.

The power source module 1150 may supply power to the components of the electronic device 1000. The power source module 1150 may include a battery that charges the power source voltage. The battery may include a non-rechargeable primary battery or a rechargeable secondary battery or fuel cell. The power source module 1150 may include a power management integrated circuit (PMIC). The PMIC may supply optimized power source to each of the components described above including the display module 1140.

In concluding the detailed description, those skilled in the art will appreciate that many variations and modifications can be made to the preferred embodiments without substantially departing from the principles of the present invention. Therefore, the disclosed preferred embodiments of the invention are used in a generic and descriptive sense only and not for purposes of limitation.

What is claimed is:

1. A display device comprising:
a display panel comprising a folding area and a non-folding area; and
a cover window disposed on an upper surface of the display panel and comprising a groove overlapping the folding area,
wherein the cover window further comprises a resin layer disposed in the groove, and
wherein the resin layer has a Young's modulus of 30 MPa to 1 GPa at −20° C.

2. The display device of claim 1,
wherein the cover window includes a first surface adjacent to the upper surface of the display panel and a second surface opposite to the first surface of the cover window, and
wherein the groove is formed at the first surface of the cover window.

3. The display device of claim 2,
wherein the resin layer has a Young's modulus of 20 MPa to 2 GPa at 25° C.

4. The display device of claim 1,
wherein the cover window includes a first surface adjacent to the upper surface of the display panel and a second surface opposite to the first surface of the cover window, and
wherein the groove is formed at the second surface of the cover window.

5. The display device of claim 4,
wherein the resin layer has a Young's modulus of 10 MPa to 2 GPa at 25° C.

6. The display device of claim 1,
wherein a difference between a refractive index of the resin layer and a refractive index of the cover window is equal to or less than 0.0009.

7. The display device of claim 1, further comprising:
a polarizing member disposed between the display panel and the cover window;
a cover window protection layer disposed on the cover window;
a window coupling member disposed between the polarizing member and the cover window; and
a protection layer coupling member disposed between the cover window and the cover window protection layer.

8. The display device of claim 7,
wherein the resin layer is in contact with one of the window coupling member and the protection layer coupling member.

9. The display device of claim 1, further comprising:
a polymer film layer disposed under a lower surface, opposite to the upper surface, of the display panel;
a barrier member disposed under the polymer film layer; and
a metal plate disposed under the barrier member.

10. A display device comprising:
a display panel comprising a folding area and a non-folding area; and
a cover window disposed on the display panel,
wherein the cover window comprises:
a flat portion overlapping the non-folding area;
a slim portion provided with a groove and overlapping the folding area and having a thickness smaller than the flat portion and located on a surface of the cover window; and
a resin layer disposed in the groove of the slim portion and having a Young's modulus of 10 MPa to 2 GPa at 25° C.

11. The display device of claim 10,
wherein the resin layer has a Young's modulus of 30 MPa to 1 GPa at −20° C.

12. The display device of claim 10,
wherein a difference between a refractive index of the resin layer and a refractive index of the cover window is equal to or less than 0.0009.

13. The display device of claim 10, further comprising:
a cover window protection layer disposed on the cover window; and
a protection layer coupling member disposed between the cover window and the cover window protection layer,
wherein the resin layer is in contact with the protection layer coupling member.

14. The display device of claim 13, further comprising:
a polarizing member disposed between the display panel and the cover window;
a polarizing member coupling member disposed between the display panel and the polarizing member; and
a window coupling member disposed between the polarizing member and the cover window.

15. The display device of claim 14, further comprising:
a polymer film layer disposed under the display panel;
a barrier member disposed under the polymer film layer; and
a metal plate disposed under the barrier member.

16. The display device of claim 10, wherein the slim portion is located on an upper surface of the cover window.

17. The display device of claim 10, wherein the slim portion is located on a lower surface of the cover window.

18. An electronic device, comprising:
a processor;
a memory having stored application programs for execution by the processor;
a display panel comprising:
a display panel comprising a folding area and a non-folding area; and
a cover window disposed on an upper surface of the display panel and comprising a groove overlapping the folding area,
wherein the cover window further comprises a resin layer disposed in the groove, and
wherein the resin layer has a Young's modulus of 30 MPa to 1 GPa at −20° C.; and
a user interface configured to sense user input via touch or cursor select of an icon presented on the display panel, wherein the processor is caused to execute one or more of the stored application programs upon receipt of the user input.

19. The electronic device of claim 18,
wherein the stored application programs include one or more of a camera application, an audiovisual streaming application, or a telephone application, and
wherein the user interface is a touch screen embedded in the display panel, wherein the touch screen includes touch sensors for sensing a touch or a tap by a user.

20. The electronic device of claim 18,
wherein the user interface includes an audio sensor embedded in the display panel,
wherein the audio sensor is configured to receive voice commands to cause access to one or more of the application programs, and
wherein the cover window is provided with a groove accommodating the resin layer.
